(19) United States
(12) Patent Application Publication
(10) Pub. No.: US 2026/0338332 A1
(43) Pub. Date: Oct. 29, 2026

(54) Method Of Manufacturing An LED Filament

(71) Applicant: SIGNIFY HOLDING B.V., EINDHOVEN (NL)

(72) Inventors: TIES VAN BOMMEL, HORST (NL); RIFAT ATA MUSTAFA HIKMET, EINDHOVEN (NL)

(21) Appl. No.: 19/491,101

(22) PCT Filed: Jun. 10, 2024
(86) PCT No.: PCT/EP2024/065868

§ 371 Date: Dec. 8, 2025

(30) Foreign Application Priority Data
Jun. 12, 2023 (EP) 23178585.8

(51) Int. Cl. F21K 9/90; F21K 9/232

(52) U.S. Cl. CPC F21K 9/90; F21K 9/232

(57) ABSTRACT

A method of manufacturing a bent LED filament (10; 10′), comprising: providing a carrier (12), wherein N≥3 parallel rows (14) of LEDs (16) are arranged on the carrier, wherein LEDs in each row of LEDs are electrically connected with a row electrical connection (18), and wherein an elongated opening (22) in the carrier is provided between each two adjacent rows of LEDs, resulting in at least N-1 elongated openings, each elongated opening extending along the length (L) of the two adjacent rows of LEDs and forming neighboring segments (26a-b, 26b-c) of the carrier; providing one or more encapsulants (32) onto the rows of LEDs such that the one or more encapsulants cover the N≥3 parallel rows of LEDs and at least part of the carrier; cutting the carrier at only one end (34) of each neighboring segments, such that i) a meandering carrier and LED filament (10) or ii) a comb-shaped carrier and LED filament (10′) is formed, wherein the other ends of the neighboring segments (26a-b, 26b-c) are connected via a connection portion (36) of the carrier; and bending the carrier at the connection portions such that i) a bent meandering carrier and LED filament (10) or ii) a bent comb-shaped carrier and LED filament (10′) is formed.

### FIELD OF THE INVENTION

The present invention relates to method of manufacturing an LED (light emitting diode) filament. The present invention also relates to an LED filament. The present invention also relates to an LED filament lamp comprising such an LED filament.

### BACKGROUND OF THE INVENTION

A trend in lighting is LED filament lamps. An LED filament lamp is an LED lamp which is designed to resemble a traditional incandescent light bulb with a visible filament for aesthetic and light distribution purposes, but with the high efficiency of light-emitting diodes.

LED filaments are manufactured by punching a PCB (FIGS. 1a-b) followed by dispensing a luminescent/scattering material silicone encapsulation material onto LED arrays arranged on said PCB obtaining encapsulation (FIG. 1c). Subsequently, segments are cut out of said PCB forming the LED filament once electrical contacts have been applied on both ends, see FIGS. 1c-d.

Moreover, US20170167663A1 discloses a lighting device comprising a plurality of solid state lighting (SSL) elements such as LEDs. The lighting device has a luminous arrangement comprising opposing tubular portions in between which strip-shaped portions that carry the SSL elements radially extend. The luminous arrangement is mounted on a support structure fitted inside a transmissive body of the lighting device.

WO 2013/078180 discloses an article comprising a flexible circuit comprising a polymeric dielectric layer having first and second major surfaces, one or both of the first and second major surfaces having a conductive layer thereon, wherein at least one conductive layer comprises an electrical circuit configured to power one or more light emitting semiconductor devices located on the flexible circuit, wherein the flexible circuit is shaped to form a three dimensional structure.

### SUMMARY OF THE INVENTION

It is an object of the present invention to improve performance (e.g. reliability) and/or the manufacturing process of LED filaments.

According to a first aspect of the invention, this and other objects are achieved by a method of manufacturing a bent LED filament, comprising: providing a carrier, wherein N≥3 parallel rows of LEDs are arranged on the carrier, wherein LEDs in each row of LEDs are electrically connected with a row electrical connection, and wherein an elongated opening in the carrier is provided between each two adjacent rows of LEDs, resulting in at least N-1 elongated openings, each elongated opening extending along the length of the two adjacent rows of LEDs and forming neighboring segments of the carrier; providing one or more encapsulants onto the rows of LEDs such that the one or more encapsulants cover the N≥3 parallel rows of LEDs and at least part of the carrier; cutting the carrier at only one end of each neighboring segments, such that i) a meandering carrier and LED filament or ii) a comb-shaped carrier and LED filament is formed, wherein the other ends of the neighboring segments are connected via a connection portion of the carrier; and bending the carrier at the connection portions such that i) a bent meandering carrier and LED filament or ii) a bent comb-shaped carrier and LED filament is formed, whereby the bent LED filament is formed. The present invention allows different/advanced LED filament structures comparable with using individual LED filaments, but without the need of individually connecting any individual LED filaments.

It can be noted that in the prior art method shown in FIGS. 1a-d, the printed circuit board is cut at both ends of each segment, such that several individual straight LED filaments are formed. And in US20170167663A1, the ends of the strip-shaped portions on which the SSL elements are arranged are not cut, and a lantern-like or globe-like structure is formed.

The carrier may have at least one bendable section in each connection portion, wherein each connection portion is bent at the at least one bendable section. The bendable section may have a smaller width and/or height than the segments of the carrier on which the rows of LEDs are arranged. Because of the smaller width and/or height of the bendable section, the carrier can easily be bent at the connection portions.

Each connection portion may have an electrical connection, wherein the electrical connections and the row electrical connections form a meandering or comb-shaped electrical connection. The electrical connection may be adapted to electrically connect the rows of LEDs of neighboring segments in series or in parallel.

Cutting the carrier may be perform after provision of the elongated openings in the carrier. Alternatively, cutting the carrier may be perform concurrent with providing the elongated openings in the carrier. At least one of cutting the carrier and provisioning the elongated openings in the carrier may preferably be performed after the electrical connections and the LEDs have been arranged on the carrier and also after the one or more encapsulants have been provided, because arranging the electrical connections and the LEDs and providing the one or more encapsulants is easier when the carrier is still well fixed/rigid.

In one embodiment, cutting the carrier at only one end of each neighboring segments includes cutting the carrier at alternating ends of the neighboring segments, such that a meandering carrier and LED filament is formed. The meandering carrier may be bent at the connection portions, whereas the segments on which the rows of LEDs are arranged remain straight, into a crossed configuration of the meandering LED filament (for example as illustrated in FIG. 5 of the drawings). An angle o between the segments and a longitudinal axis of the LED filament in the crossed configuration is preferably 5°≤φ≤45°.

In another embodiment, cutting the carrier at only one end of each neighboring segments includes cutting the carrier at the same end of each neighboring segments, such that a comb-shaped carrier and LED filament is formed. The comb-shaped carrier may be bent at the connection portions, whereas the segments on which the rows of LEDs are arranged remain straight, into an umbrella-like configuration of the comb-shaped LED filament (for example as illustrated in FIGS. 6a-b of the drawings). An angle a between segments in a plane vertical to a longitudinal axis of the LED filament in the umbrella-like configuration may be 360°/N. Moreover, an angle φ between the segments and the longitudinal axis is here preferably 5°≤φ≤45°.

The elongated opening may have an opening length OL and an opening width OW, wherein OL≥30 mm, OW≥5 mm, and OL/OW≥10.

Electrical contacts may be applied to one end or both ends of the meandering or comb-shaped LED filament for powering the meandering or comb-shaped LED filament.

The carrier may be a printed circuit board (PCB), in particular a metal core printed circuit board. The metal layer in the metal core PCB may beneficially be used to keep the present LED filament in the bent configuration.

The one or more encapsulants may comprise at least one of i) a luminescent material configured to at least partly convert LED light emitted by the LEDs into converted light and ii) a scattering material configured to at least partly scatter LED light emitted by the LEDs into scattered light. The luminescent material may for example be or comprise phosphor. The scattering material may for example be or comprise light scattering particles, such as for example BaS0₄, Ti0₂, and/or Al₂O₃.

According to a second aspect of the invention, there is provided an LED filament manufactured by the method according to the first aspect of the invention.

In one embodiment, the LED filament of the second aspect may also/alternatively be defined as: a meandering LED filament, comprising: a meandering carrier with N≥4 segments, each on which one of N rows of LEDs is arranged, wherein the LEDs in each row of LEDs are electrically connected with a row electrical connection, wherein one or more encapsulants are provided (e.g. dispensed) onto the rows of LEDS, wherein ends of neighboring segments of the carrier are connected via a connection portion of the carriers, and wherein the meandering LED filament optionally is bent at the connection portions, whereas the segments on which the rows of LEDs are arranged remain straight, into a crossed configuration.

In another embodiment, the LED filament of the second aspect may also/alternatively be defined as: a comb-shaped LED filament, comprising a comb-shaped carrier with N≥3 segments, each on which one of N rows of LEDs is arranged, wherein the LEDs in each row of LEDs are electrically connected with a row electrical connection, wherein one or more encapsulants are provided (e.g. dispensed) onto the rows of LEDS, wherein ends of neighboring segments of the carrier are connected via a connection portion of the carriers, and wherein the comb-shaped LED filament optionally is bent at the connection portions, whereas the segments on which the rows of LEDs are arranged remain straight, into an umbrella-like configuration.

According to a third aspect of the invention, there is provided an LED filament lamp, comprising: an LED filament according to the second aspect of the invention; an envelope at least partly enclosing said LED filament; and a base for electrically-mechanically connecting said LED filament lamp to a socket of a luminaire.

It is noted that the invention relates to all possible combinations of features recited in the claims.

### BRIEF DESCRIPTION OF THE DRAWINGS

These and other aspects of the present invention will now be described in more detail, with reference to the appended drawings showing embodiment(s) of the invention.

FIGS. 1a-d illustrate a prior art method of manufacturing LED filaments.

FIG. 2 is a flow chart of a method of manufacturing an LED filament according to an aspect of the present invention.

FIGS. 3a-d illustrate a method of manufacturing a meandering LED filament according to an embodiment of the present invention.

FIGS. 4a-d illustrate a method of manufacturing a comb-shaped LED filament according to another embodiment of the present invention.

FIG. 5 is a side view of an LED filament lamp comprising a meandering LED filament bent into a crossed configuration.

FIG. 6a is a side view of an LED filament lamp comprising a comb-shaped LED filament bent into an umbrella-like configuration.

FIG. 6b is a top view of the LED filament in FIG. 6a.

As illustrated in the figures, the sizes of layers and regions may be exaggerated for illustrative purposes and, thus, are provided to illustrate the general structures of embodiments of the present invention. Like reference numerals refer to like elements throughout.

### DETAILED DESCRIPTION

The present invention will now be described more fully hereinafter with reference to the accompanying drawings, in which currently preferred embodiments of the invention are shown. This invention may, however, be embodied in many different forms and should not be construed as limited to the embodiments set forth herein; rather, these embodiments are provided for thoroughness and completeness, and fully convey the scope of the invention to the skilled person.

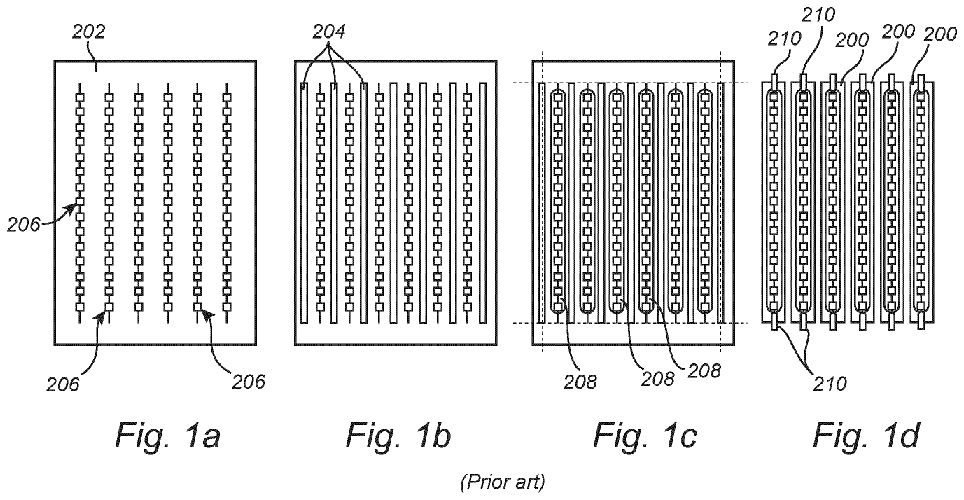

FIGS. 1a-d illustrate a prior art method of manufacturing individual, straight LED filaments 200. The LED filaments 200 are manufactured by punching a PCB 202 forming openings 204 (FIGS. 1a-b), followed by dispensing a luminescent/scattering material silicone encapsulation material onto LED arrays 206 arranged on said PCB obtaining encapsulation 208 (FIG. 1c). Subsequently, segments are cut out (as illustrated by the dashed lines in FIG. 1c) of said PCB forming the LED filaments 200 (FIG. 1d) once electrical contacts 210 have been applied on both ends.

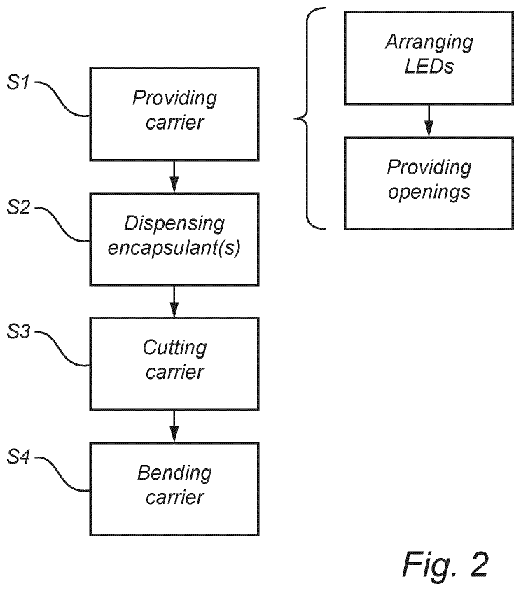

With reference to FIGS. 2-4, a manufacturing method and LED (light emitting diode) filaments 10, 10′ according to aspects of the present invention will be described. The manufacturing method may be performed partly or fully automatically, using or more manufacturing apparatuses.

At S1, a carrier 12 is provided. The carrier 12 may for example be a metal core printed circuit board. The carrier 12 may for example be square or rectangular.

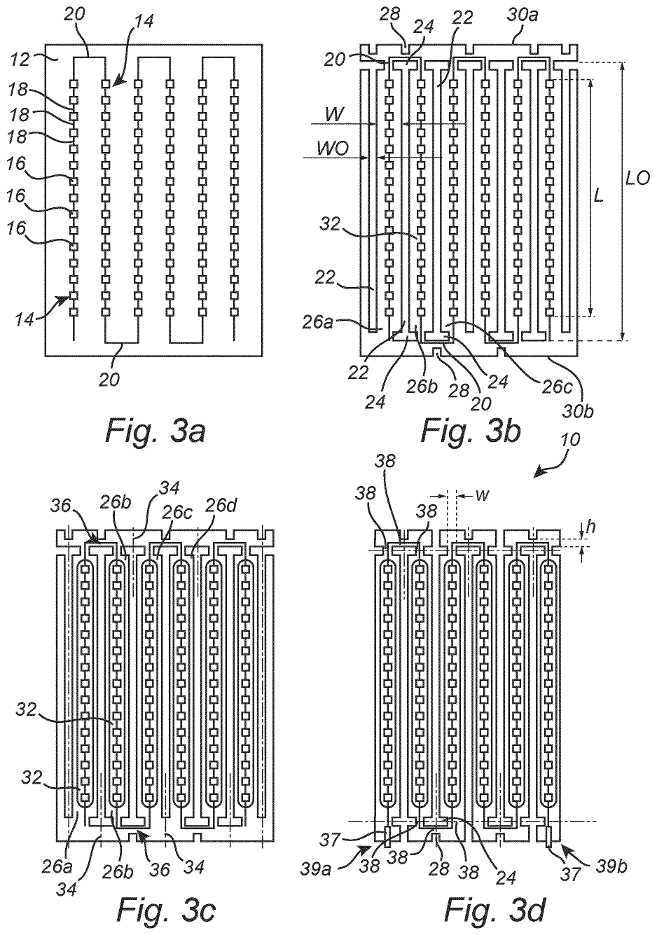

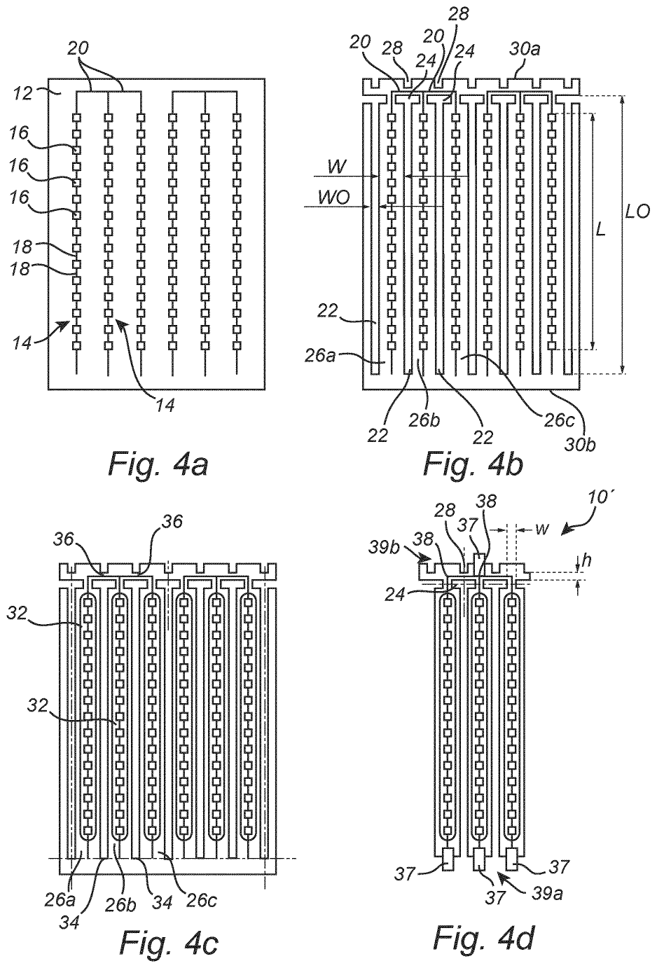

On a (major) surface of the carrier 12, N parallel rows 14 of LEDs 16 are arranged, see FIGS. 3a and 4a. Thus, providing the carrier 12 may include the step of arranging/mounting N parallel rows 14 of LEDs 16 on the carrier. N≥3, for example N=6 as in FIGS. 3a and 4a. The LEDs 16 may be adapted to emit LED light. The LEDs 16 may for example be blue LEDs adapted to emit blue LED light. The number of LEDs 16 in each row may for example be at least 10, preferably at least 15, more preferably at least 20, most preferably at least 25 such as 30 or 40 LEDs.

The LEDs 16 in each row of LEDs are electrically connected with a row electrical connection 18. Moreover, the rows 14 of LEDs 16 are electrically connected with electrical connections 20. In FIG. 3a, the row electrical connections 18 and the electrical connections 20 form a meandering, serial electrical connection. In FIG. 4a, the row electrical connections 18 and the electrical connections 20 form a comb-shaped, parallel electrical connection. The electrical connections 18 and 20 may for example be copper electrical connections.

Between each two adjacent rows 14 of LEDs 16, an elongated opening 22 is provided in the carrier 12, see FIGS. 3b and 4b. Thus, providing the carrier 12 may include the step of providing an elongated opening 22 in the carrier 12 between each two adjacent rows 14 of LEDs 16. The carrier 12 thus has at least N-1 elongated openings 22. The elongated openings 22 may for example be provided by punching.

Each elongated opening 22 may extend along at least the complete length L of the rows 14 of LEDs 16. Specifically, the length LO of each elongated opening 22 may (slightly) exceed the length L of the rows 14 of LEDs 16. The opening length LO may for example be ≥30 mm, whereas the opening width OW may be ≤5 mm. Preferably OL/OW≥10. Each elongated opening 22 may be straight. Moreover, each elongated opening 22 may have a T-shape 24 at one or both of its ends. In FIG. 3b, the elongated opening 22 between each two adjacent rows 14 of LEDs 16 has a T-shape 24 at both of its ends. In FIG. 4b, the elongated opening 22 between each two adjacent rows 14 of LEDs 16 has a T-shape 24 at only one of its ends; notably all elongated openings 18 here has the T-shape 24 at the same end.

Each elongated opening 22 may form neighboring segments 26a-b, 26b-c of the carrier 12. Hence, the carrier 12 may have N segments 26a-c, each on which one of the N rows 14 of LEDs 16 is arranged. Preferably L>5W, where W is the width of each segment 26a-c.

Optionally, notches 28 may be formed at one or more edges 30a-b of the carrier. The notches 28 would be aligned with the electrical connections 20 and the T-shapes 24 of the elongated openings 22.

At S2, the manufacturing method may comprise providing, preferably dispensing, one or more encapsulants 32 onto the rows 14 of LEDs 16, such that the one or more encapsulants 32 cover the rows 14 of LEDs 16 and part of the carrier 12. The one or more encapsulants 32 may comprise a luminescent material configured to at least partly convert the LED light emitted by the LEDs 16 into converted light. The converted light and unconverted LED light may form LED filament light, in particular white LED filament light. The luminescent material may for example be or comprise phosphor. Moreover, the one or more encapsulants 32 may comprise a scattering material configured to at least partly scatter the LED light emitted by the LEDs 16 into scattered light The scattering material may for example be or comprise light scattering particles, such as for example BaS0₄, Ti0₂, and/or Al₂O₃.

At S3, the manufacturing method may comprise cutting (as indicated by the dash dot lines in FIGS. 3c and 4c) the carrier 12 at only one end 34 of each neighboring segments 26a-b, 26b-c, such that i) a meandering carrier 12 and a meandering LED filament 10 or ii) a comb-shaped carrier 12 and a comb-shaped LED filament 10′ are formed, whereas the other ends of the neighboring segments 26a-b, 26b-c are connected via a connection portion 36 of the carrier 12. Each connection 36 may have one of the electrical connections 20. Cutting the carrier 12 may for example be performed after providing the elongated openings 22 in the carrier.

In one embodiment, cutting the carrier 12 at only one end 34 of each neighboring segments 26a-b, 26b-c may include cutting the carrier 12 at alternating ends of the neighboring segments 26a-b, 26b-c as shown in FIG. 3c, such that the meandering carrier and LED filament 10 is formed (FIG. 3d). Specifically, the carrier 12 may here be cut from the elongated opening 22 to the edge 30a-b of the carrier 12 at alternating ends of the neighboring segments 26a-b, 26b-c, as indicated by vertical dash dot lines in FIG. 3c.

In another embodiment, cutting the carrier 12 at only one end 34 of each neighboring segments 26a-b, 26b-c may include cutting the carrier 12 at the same end of each neighboring segments 26a-b, 26b-c as shown in FIG. 4c, such that the comb-shaped carrier and LED filament 10′ is formed (FIG. 4d). Specifically, the carrier 12 may here be cut through the elongated openings 22 of the carrier 12 at the same end of each neighboring segments 26a-b, 26b-c, as indicated by the horizontal dash dot line in FIG. 4c.

The manufacturing method may also comprise applying electrical contacts 37 to one or both ends 39a-b of the LED filament 10, 10′ powering the LED filament 10, 10′, for example as illustrated in FIG. 3d or 4d.

At S4, the manufacturing method may further comprise bending (as indicated by the dash dot lines in FIGS. 3d and 4d) the carrier 12 at the connection portions 36, whereas the segments 26a-b, 26b-c on which the rows 14 of LEDs 16 are arranged remain straight/unbent, such that i) a bent meandering carrier 12 and a bent meandering LED filament 10 or ii) a bent comb-shaped carrier 12 and a bent comb-shaped LED filament 10′ are formed. To this end, the carrier 12 may have at least one bendable section 38 in each carrier connection portion 36. Some bendable sections 38 may have a smaller width w than the segments 26a-b, 26b-c of the carrier 12 on which the rows 14 of LEDs 16 are arranged. The smaller width w may for example be in the range of 20%-80% of the width W of the segments 26a-b, 26b-c. The smaller width w may be realized by two adjacent T-shapes 24. Other bendable sections 38 may have small/limited height h, as realized by a notch 28 and an adjacent opening 22, optionally with a T-shape 24. The height h of the bendable sections 38 may for example be 3-30% of LO. Each connection portion 36 may for example have triple bendable sections 38; a first bendable section 38 with reduced width w at the end of one segment (e.g. 26a) of the neighboring segments, a second bendable section 38 with reduced width w at the end of the other segment (e.g. 26b) of the neighboring segments, and a third intermediate bendable section 38 with limited height h.

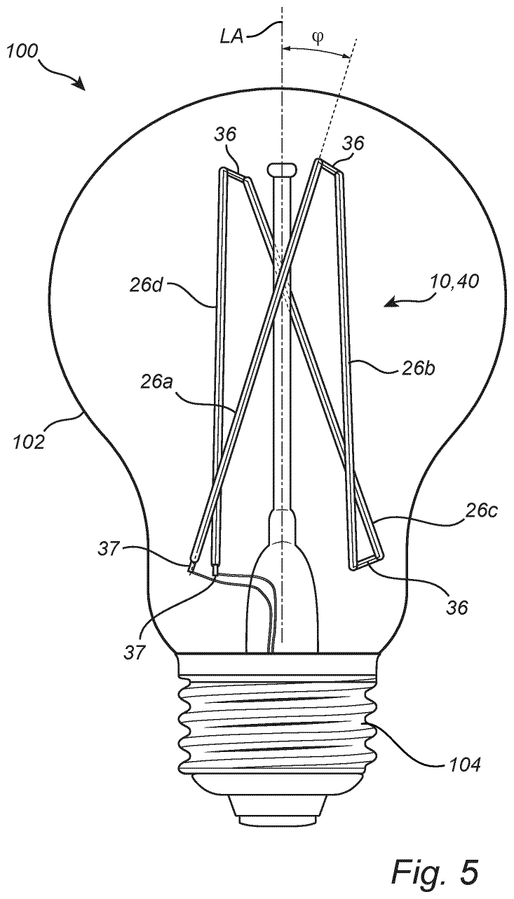

With further reference to FIG. 5, in one embodiment, the meandering carrier 12 may be bent into a crossed configuration 40 of the meandering LED filament 10. Here, N=4, but it could alternatively for example be 6. In the crossed configuration 40, two or more of the segments 26a-d cross each other as seen from one or more sides of the bent meandering LED filament 10. Moreover, from above (top view), this configuration can be seen as a 360° configuration. Moreover, the angle o between each segment 26a-d and a longitudinal axis LA of the LED filament 10 in the crossed configuration 40 is preferably 10°≤φ≤45°. Moreover, the diameter of the bent meandering LED filament 10 at the bottom may be (slightly) larger than the diameter at the top of the bent meandering LED filament 10. It should be noted that commercially available LED lamps also have crossed configurations, but in those lamps the crossed configuration is realized by four separate straight LED filaments, not a single bent meandering LED filament 10 as in the present invention.

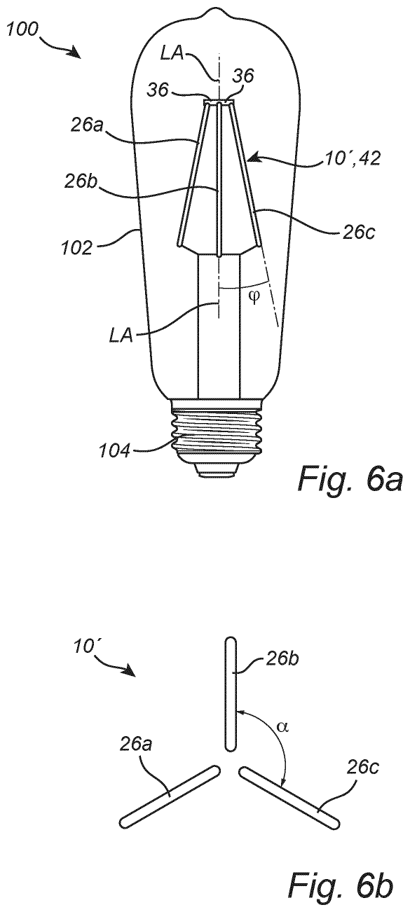

With further reference to FIGS. 6a-b, in another embodiment, the comb-shaped carrier 12 may be bent into an umbrella-like configuration 42 of the comb-shaped LED filament 10′. Here, N=3, but it could alternatively for example be 4, 6, 8, etc. In the umbrella-like configuration 42, the segments 26a-c may be seen as radiating from the longitudinal axis LA, obliquely downwards and outwards from the connection portions 36. The angle α between the segments 26a-c in a plane vertical to the longitudinal axis LA of the LED filament 10′ in the umbrella-like configuration 42 may be 360°/N. Hence, from above (top view), this configuration can be seen as a 360°configuration Moreover, the angle o between each segment 26a-c and the longitudinal axis LA is preferably 10°≤q≤45°. Moreover, the diameter of the bent comb-shaped LED filament 10′ at the bottom may be larger than the diameter at the top of the comb-shaped meandering LED filament 10′. It should be noted that commercially available LED lamps also have umbrella-like configurations, but in those lamps the umbrella-like configuration is realized by say three separate straight LED filaments, not a single bent comb-shaped LED filament 10′ as in the present invention.

As also shown in FIG. 5 and FIG. 6a, an LED filament lamp 100 according to an aspect of the present invention comprises the LED filament 10, 10′, respectively. The LED filament lamp 100 may for example be a retrofit bulb. The LED filament lamp 100 further comprises an envelope 102 at least partly enclosing the LED filament 10, 10′. The envelope 102 may for example be transparent. The envelope 102 may for example be made of glass. The envelop 102 may have various shapes, such as bulb, candle, etc. The LED filament lamp 100 further comprises a base 104 for electrically-mechanically connecting the LED filament lamp to a socket of a luminaire (not shown). The base 104 can be of various types known per se, for example E14 or E27.

The person skilled in the art realizes that the present invention by no means is limited to the preferred embodiments described above. On the contrary, many modifications and variations are possible within the scope of the appended claims. For example, cutting the carrier 12 may be perform concurrent with/in the same operation as providing the elongated openings 22 in the carrier 12. Moreover, cutting the carrier 12 and providing the elongated openings 22 could be performed after the one or more encapsulants 32 have been dispensed. Moreover, the openings 22 could be provided before the LEDs 16 are arranged on the carrier 12.

Additionally, variations to the disclosed embodiments can be understood and effected by the skilled person in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measured cannot be used to advantage.

1. A method of manufacturing a bent LED filament comprising:
providing a carrier, wherein N≥3 parallel rows of LEDs are arranged on the carrier, wherein LEDs in each row of LEDs are electrically connected with a row electrical connection, and wherein an elongated opening in the carrier is provided between each two adjacent rows of LEDs, resulting in at least N-1 elongated openings, each elongated opening extending along the length of the two adjacent rows of LEDs and forming neighboring segments of the carrier;
providing one or more encapsulants onto the rows of LEDs such that the one or more encapsulants cover the N≥3 parallel rows of LEDs and at least part of the carrier;
cutting the carrier at only one end of each neighboring segments includes cutting the carrier at alternating ends of the neighboring segments, such that a meandering carrier and LED filament is formed, wherein the other ends of the neighboring segments are connected via a connection portion of the carrier; and
bending the carrier at the connection portions such that a bent meandering carrier and LED filament is formed, whereby the bent LED filament is formed, and wherein the segments on which the rows of LEDs are arranged remain straight, into a crossed configuration of the meandering LED filament, wherein an angle (φ) between the segments and a longitudinal axis of the LED filament in the crossed configuration is 5°≤φ≤45°.

2. A method according to claim 1, wherein the carrier has at least one bendable section in each connection portion, and wherein each connection portion is bent at the at least one bendable section.

3. A method according to claim 2, wherein the bendable section has a smaller width and/or height than the segments of the carrier on which the rows of LEDs are arranged.

4. A method according to claim 1, wherein each connection portion has an electrical connection, wherein the electrical connections and the row electrical connections form a meandering electrical connection.

5. A method according to claim 1, wherein cutting the carrier is performed after provision of the elongated openings in the carrier.

6. (canceled)

7. (canceled)

8. A method according to claim 1, wherein the elongated opening has an opening length (OL) and an opening width (OW), wherein OL≤30 mm, OW≤5 mm, and OL/OW≥10.

9. A method according to claim 1, wherein electrical contacts are applied to at least one end of the meandering LED filament for powering the meandering or comb-shaped LED filament.

10. A method according to claim 1, wherein the carrier is a metal core printed circuit board.

11. A method according to claim 1, wherein the one or more encapsulants comprise at least one of i) a luminescent material configured to at least partly convert LED light emitted by the LEDs into converted light and ii) a scattering material configured to at least partly scatter LED light emitted by the LEDs into scattered light.

12. An LED filament comprising:
a carrier, wherein N≥3 parallel rows of LEDs are arranged on the carrier, wherein LEDS in each row of LEDs are electrically connected with a row electrical connection, and wherein an elongated opening in the carrier is provided between each two adjacent rows of LEDs, resulting in at least N-1 elongated openings, each elongated opening extending along the length of the two adjacent rows of LEDs and forming neighboring segments of the carrier; and
one or more encapsulants onto the rows of LEDs such that the one or more encapsulants cover the N≥3 parallel rows of LEDs and at least part of the carrier;
wherein the carrier is cut at only one end of each neighboring segments, wherein the carrier is cut at alternating ends of the neighboring segments such that a meandering carrier and LED filament is formed, wherein the other ends of the neighboring segments are connected via a connection portion of the carrier, and
wherein the carrier is bent at the connection portions such that a bent meandering carrier and LED filament is formed, whereby the bent LED filament is formed, and wherein the segments on which the rows of LEDs are arranged remain straight, into a crossed configuration of the meandering LED filament, wherein an angle (φ) between the segments and a longitudinal axis of the LED filament in the crossed configuration is 5°≤φ≤45°.

13. An LED filament lamp, comprising:
the LED filament according to claim 12;
an envelope at least partly enclosing said LED filament; and
a base for electrically-mechanically connecting said LED filament lamp to a socket of a luminaire.
